(19) United States
(12) Patent Application Publication
(10) Pub. No.: US 2026/0304658 A1
(43) Pub. Date: Oct. 1, 2026

(54) DISPLAY APPARATUS

(71) Applicant: LG Display Co., Ltd., Seoul (KR)

(72) Inventor: Min San JO, Paju-si (KR)

(73) Assignee: LG Display Co., Ltd., Seoul (KR)

(21) Appl. No.: 19/414,888

(22) Filed: Dec. 10, 2025

(30) Foreign Application Priority Data
Mar. 26, 2025 (KR) 10-2025-0038946

(51) Int. Cl. H05K 5/03

(52) U.S. Cl. CPC H05K 5/03

(57) ABSTRACT

A display apparatus is provided. The display apparatus includes a cover glass, a display panel disposed on the cover glass and configured to display an image on a front-side surface thereof, a flexible printed circuit board disposed in a partial region of a backside surface of the display panel, a first frame including a first portion covering the flexible printed circuit board, a second portion covering an edge of the backside surface of the display panel, and a stepped portion connecting the first portion to the second portion and provided to be inclined, a first adhesive layer disposed between the first portion of the first frame and the flexible printed circuit board and between the second portion of the first frame and the display panel, a housing accommodating the first frame and the display panel therein and coupled to an outer surface of the cover glass, and a second frame disposed along the first frame and disposed in a first space formed between a side surface of the flexible printed circuit board and the stepped portion of the first frame, wherein the first adhesive layer includes a trapping cavity forming a space between the display panel and the first frame, and the space formed by the trapping cavity is connected to the first space.

### CROSS-REFERENCE TO RELATED APPLICATIONS

This application claims the benefit of the Korean Patent Application No. 10-2025-0038946 filed on Mar. 26, 2025, which is hereby incorporated by reference as if fully set forth herein.

### BACKGROUND

### Technical Field

The present disclosure relates to a display apparatus.

### Description of the Related Art

As information technology advances, the market for display apparatuses which are connection mediums connecting a user with information is increasing. Therefore, the use of display apparatuses such as light emitting display apparatuses, quantum dot display (QDD) apparatuses, and liquid crystal display (LCD) apparatuses is increasing.

In display apparatuses, a display panel which displays an image on a front-side surface thereof may be disposed and assembled in a space formed by a cover glass and a housing. A set structure having various functions may be disposed on a backside surface of the display panel.

Recently, various technologies are being researched for enhancing a waterproof function of display apparatuses.

### BRIEF SUMMARY

The present disclosure provides a display apparatus in which a waterproof function may be enhanced, and the warpage of a cover glass may be prevented.

As embodied and broadly described herein, a display apparatus includes a cover glass, a display panel disposed on the cover glass and configured to display an image on a front-side surface, a flexible printed circuit board disposed on a partial region of a backside surface of the display panel, a first frame including a first portion covering the flexible printed circuit board, a second portion covering an edge of the backside surface of the display panel, and a stepped portion connecting the first portion to the second portion and provided to be inclined, a first adhesive layer disposed between the first portion of the first frame and the flexible printed circuit board and between the second portion of the first frame and the display panel, a housing accommodating the first frame and the display panel therein and coupled to an outer surface of the cover glass, and a second frame disposed along the first frame and disposed in a first space formed between a side surface of the flexible printed circuit board and the stepped portion of the first frame, wherein the first adhesive layer includes a trapping cavity forming a space between the display panel and the first frame, and the space formed by the trapping cavity is connected to the first space.

The trapping cavity may be surrounded by the first adhesive layer.

The first space may include a bending portion extending along an outer side of the flexible printed circuit board and bent, and the trapping cavity may be disposed to contact the bending portion of the first space.

A greatest width forming an area of the trapping cavity may be greater than a width of the stepped portion.

A height of the trapping cavity may be the same as a thickness of the first adhesive layer.

The second frame may be disposed in the trapping cavity.

The second frame may be disposed in a second space formed between the housing, a backside surface of an edge of the cover glass, an outer surface of the display panel, and an outer surface of the first frame.

An outer end of the first frame may be spaced apart from the display panel or the cover glass, and the second frame may be disposed in at least one of a region between an outer end of the first frame and a side surface of the display panel and a region between the outer end of the first frame and an edge of the cover glass.

The second frame may be disposed in a third space formed between the housing and the first frame.

The first frame and the second frame may include different materials.

The first frame may include a metal material, and the second frame may include a polymer including resin or plastic.

An interval up to the first portion of the first frame from the backside surface of the display panel may be greater than an interval up to the second portion of the first frame from the backside surface of the display panel.

The display apparatus may further include a second adhesive layer disposed between the housing and the second frame disposed in the second space.

Each of the first and second adhesive layers may include a pressure sensitive adhesive (PSA).

The display apparatus may further include a data driving chip disposed on the flexible printed circuit board to supply the display panel with a data voltage for displaying an image, wherein the first portion of the first frame may be disposed on the data driving chip.

The display apparatus may further include a reinforcing plate disposed on the flexible printed circuit board and including a metal material, wherein the first portion of the first frame may be disposed on the reinforcing plate.

Embodiments of the present disclosure may include a trapping cavity connected with a first space formed by a stepped portion of a first frame, in a first adhesive layer, and thus, a second frame may more precisely plug a fine gap between the first frame and a display panel to enhance waterproof performance.

In more detail, when manufacturing a display apparatus, a resin for forming the second frame may be trapped in the trapping cavity through a first space in the middle of a second frame formation process, a trapped resin may obstruct a path of resin implanted into the first space subsequently, and a subsequently implanted resin may plug a fine gap between the first frame and the display panel and may then overflow through the first space. Accordingly, the trapping cavity may further enhance a waterproof function of a display apparatus.

Moreover, in embodiments of the present disclosure, an outer end of the first frame may not contact a cover glass, and the second frame may be disposed between the first frame and the cover glass, and thus, stress applied to the display panel due to a tolerance of a first frame may be blocked, and the warpage of the cover glass may be prevented.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is an exploded perspective view for describing a display apparatus according to an embodiment of the present disclosure;

FIGS. 2A and 2B are diagrams for describing an embodiment of a structure where a flexible printed circuit board is disposed on a backside surface of a display panel;

FIG. 3 is a diagram for describing an embodiment of a structure where a first adhesive layer is disposed on a backside surface of a display panel;

FIGS. 4A to 4E are diagrams for describing an embodiment of a connection relationship between a display panel, a first adhesive layer, and a first frame according to the present disclosure;

FIGS. 5A to 5C are diagrams for describing an embodiment where a mold is coupled to a cover glass to form a second frame according to an embodiment of the present disclosure;

FIGS. 6A to 6C are diagrams for describing an embodiment of a structure where a second frame according to an embodiment of the present disclosure is disposed at an edge of each of a display panel and a cover glass; and

FIG. 7 is a diagram for describing an embodiment of a structure where a housing is coupled to a cover glass in a state where a second frame according to an embodiment of the present disclosure is disposed at an edge of each of a display panel and the cover glass.

### DETAILED DESCRIPTION

Hereinafter, embodiments will be described in detail with reference to the accompanying drawings.

Like reference numerals refer to like elements. Also, a thickness, a ratio, and a dimension of each element described herein are illustrated to be partially enlarged or reduced for convenience of effective description. A scale of each element illustrated in the drawings of the present disclosure may have a scale which differs from a real scale, for convenience of description, but is not limited to a scale illustrated in the drawings.

In the present disclosure, when an arbitrary element (or a region, a layer, a portion, etc.) is described as “being on”, “connected”, or “coupled”, this may denote that the arbitrary element may be directly connected/coupled to another element, or a third element may be disposed therebetween.

The term “and/or” may include all of one or more combinations capable of being defined by relevant elements.

Terms like a first and a second may be used to describe various elements, but the elements should not be limited by the terms. The terms may be used only as object for distinguishing an element from another element. For example, without departing from the spirit and scope of the inventive concept, a first element may be referred to as a second element, and similarly, the second element may be referred to as the first element. The terms of a singular form may include plural forms unless referred to the contrary.

The terms “under”, “below”, “on”, and “above” may be used to describe a correlation between elements illustrated in the drawings. The terms may be a relative concept and may be described with respect to a direction illustrated in the drawings. For example, unless “just” or “direct” is used, one or more other elements between two elements may be disposed. Spatially relative terms “below”, “beneath”, “lower”, “above”, and “upper” may be used herein for easily describing a relationship between one device or elements and other devices or elements as illustrated in the drawings. Therefore, for example, “under” and “lower” may be opposite to “on” and “upper” with respect to a first element.

It should be understood that spatially relative terms are terms including different orientations of elements in use or operation, in addition to the orientation illustrated in the drawings. For example, if a device in the drawings is turned over, elements described as being on the “below” or “beneath” sides of other elements may be placed on “above” sides of the other elements. Therefore, the exemplary term “lower” may include both orientations of “lower” and “upper”. Likewise, the exemplary term “above” or “upper” may include both orientations of above and below.

It should be understood that the meaning of “include,” “comprise,” “including,” or “comprising,” specifies a property, a region, a fixed number, a step, a process, an element and/or a component, but does not exclude other properties, regions, fixed numbers, steps, processes, elements and/or components.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other, or may be carried out together in co-dependent relationship.

Hereinafter, a display apparatus according to an embodiment of the present disclosure will be described with reference to the accompanying drawings.

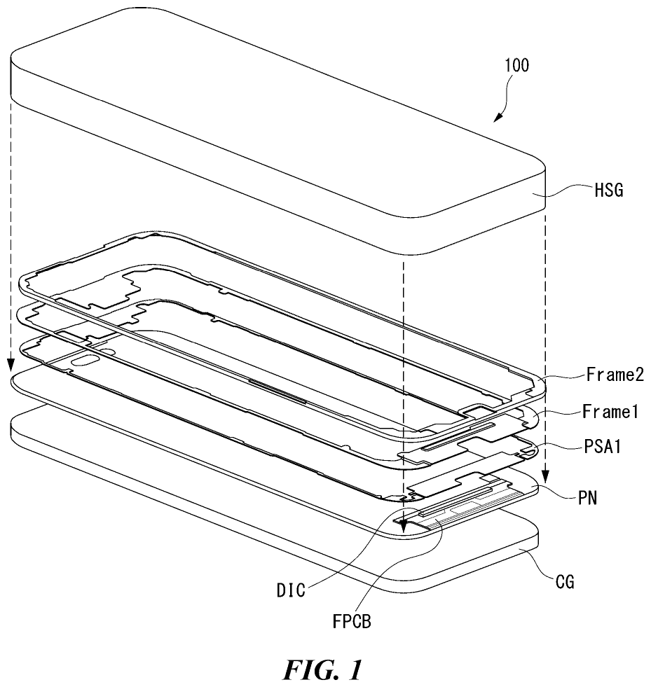

As illustrated in FIG. 1, a display apparatus 100 according to an embodiment of the present disclosure may include a cover glass CG, a display panel PN, a flexible printed circuit board FPCB, a first adhesive layer PSA1, a first frame Frame1, a second frame Frame2, and a housing HSG.

The cover glass CG may include a material having a high transmittance, and for example, may include glass. The cover glass CG may protect the display panel PN disposed inward therefrom against an external impact.

The display panel PN may be disposed on the cover glass CG and may display an image on a front-side surface thereof. In detail, a front-side surface of the display panel PN may be disposed to face the cover glass CG, and the display panel PN may display an image through the cover glass CG.

The display panel PN may include a plurality of subpixels which each include a light emitting device OLED emitting light. Each of the plurality of subpixels may include the light emitting device OLED and a pixel circuit which drives the light emitting device OLED. The light emitting device OLED may output light corresponding to one color among red (R), green (G), blue (B), and white (W). The pixel circuit may generate a current for driving the light emitting device OLED of each subpixel.

To display an image, the display panel PN may be connected to a data driver which converts digital image data, input from the outside, into analog data voltages and respectively supplies the data voltages to a plurality of subpixels. The data driver may be disposed as a chip type on the flexible printed circuit board FPCB connected to the display panel PN. Hereinafter, the data driver which is disposed on the flexible printed circuit board FPCB in order to supply a data voltage for displaying an image on the display panel PN may be referred to as a data driving chip DIC.

The flexible printed circuit board FPCB may be disposed in a partial region of a backside surface of the display panel PN, and the data driving chip DIC electrically connected to the flexible printed circuit board FPCB may be disposed in a partial region of the flexible printed circuit board FPCB. The flexible printed circuit board FPCB may transfer a signal, applied from the data driving chip DIC, to the display panel PN so as to display an image.

The first adhesive layer PSA1 may be disposed at an edge of the backside surface of the display panel PN and may attach the first frame Frame1 to the backside surface of the display panel PN. The first adhesive layer PSA1 may attach the first frame Frame1 to the display panel PN and may fix the first frame Frame1 to the backside surface of the display panel PN. The first adhesive layer PSA1 may include a pressure sensitive adhesive (PSA) including various materials such as silicon, a thermoplastic material, and an organic material. In a case where the first frame Frame1 is disposed on the backside surface of the display panel PN, the first adhesive layer PSA1 may be disposed on the backside surface of the display panel PN together, with being adhered to the first frame Frame1.

The first frame Frame1 may be disposed along an edge region of the backside surface of the display panel PN. The first frame Frame1 may include a stiff metal material such as stainless steel or aluminum and may prevent the display panel PN or the cover glass CG from being warped by an external impact.

As illustrated in FIG. 1, the first frame Frame1 may be disposed along the edge region of the display panel PN and may be disposed to cover the flexible printed circuit board FPCB disposed in a portion of the edge region of the display panel PN. The first frame Frame1 may be attached and fixed to the backside surface of the display panel PN by the first adhesive layer PSA1.

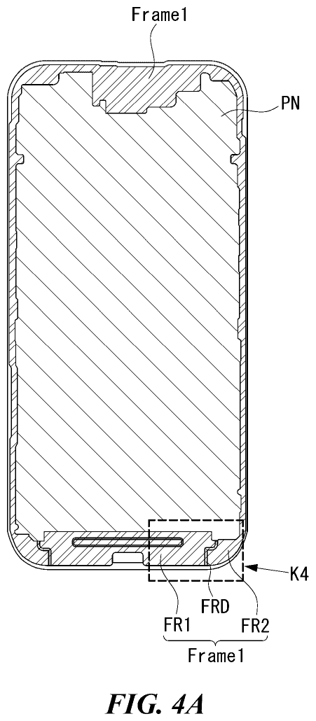

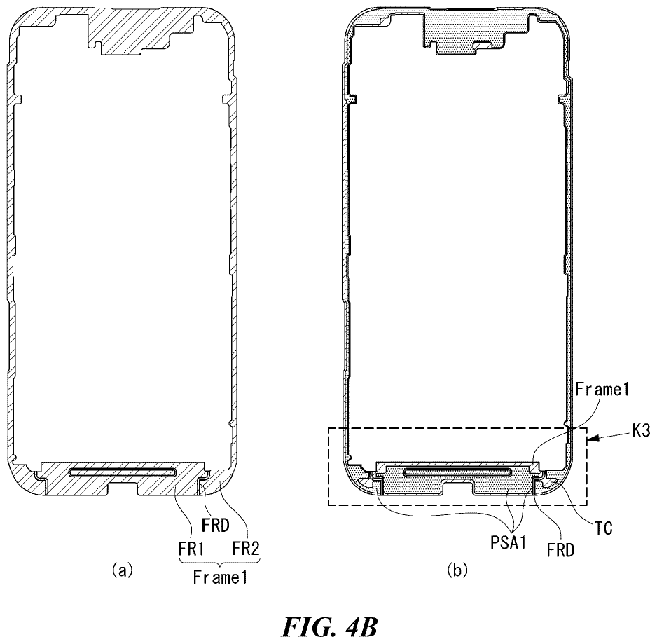

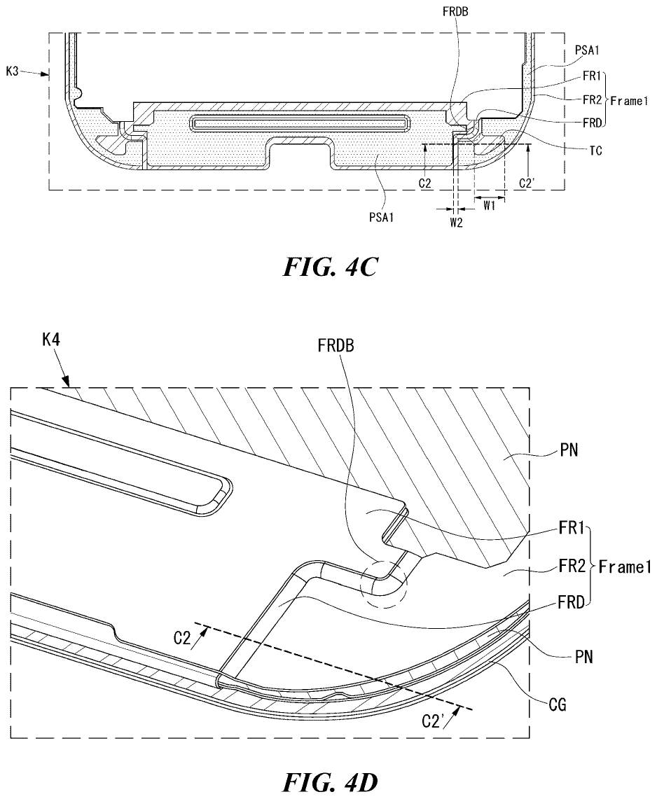

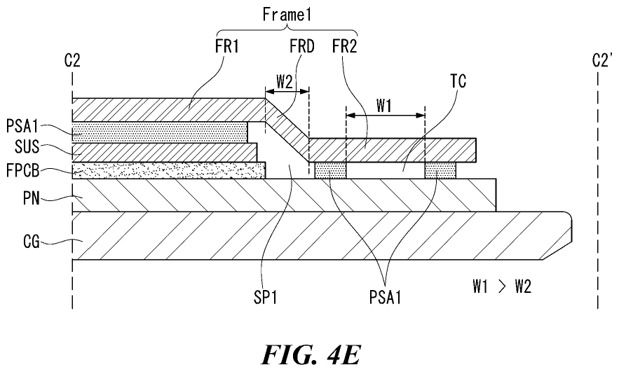

The first frame Frame1 may have a step height due to the data driving chip DIC or the flexible printed circuit board FPCB disposed on the backside surface of the display panel PN. For example, the first frame Frame1 may include a first portion covering the flexible printed circuit board FPCB and a second portion covering an edge of the backside surface of the display panel PN, and moreover, may include a stepped portion which connects the first portion to the second portion and is provided to be inclined. The first and second portions and the stepped portion of the first frame Frame1 will be described below in detail with reference to FIGS. 4A to 4E.

The second frame Frame2 may be disposed on the edge of the backside surface of the display panel PN along the first frame Frame1. The second frame Frame2 may be disposed to plug an empty gap between the cover glass CG, the display panel PN, the flexible printed circuit board FPCB, and the first frame Frame1.

The second frame Frame2 may include a material which differs from that of the first frame Frame1. For example, the second frame Frame2 may include a polymer including a resin or plastic.

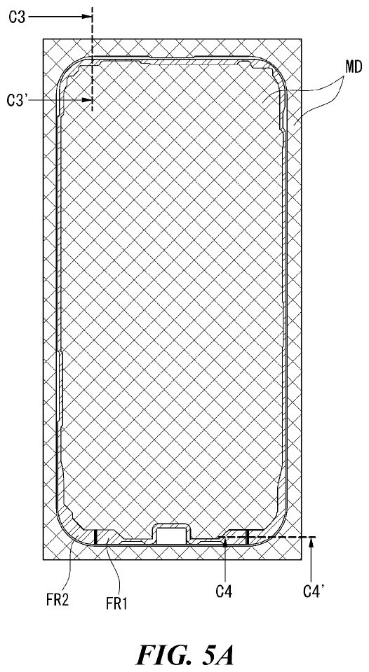

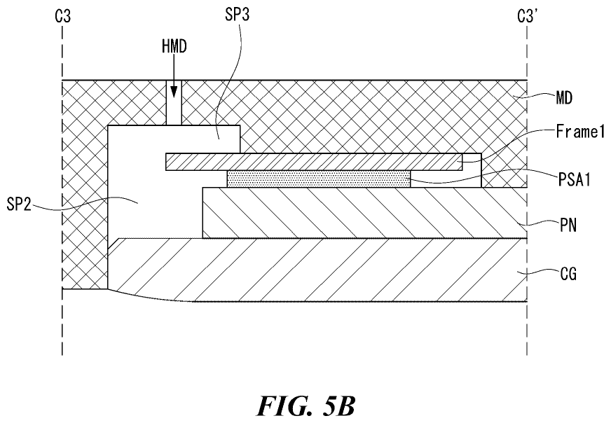

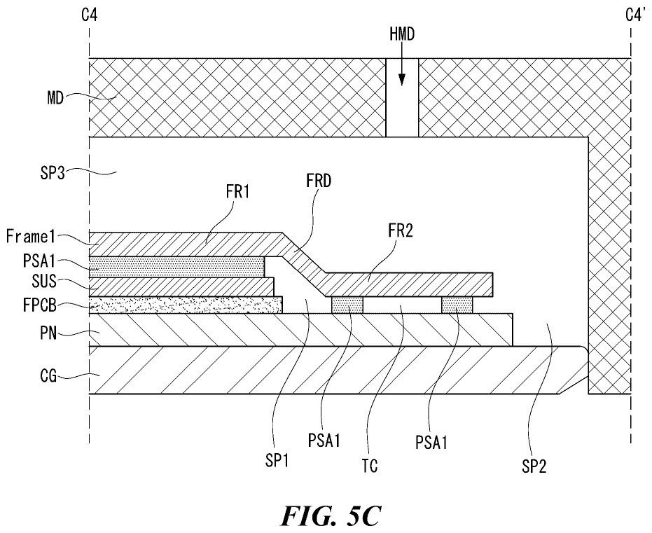

The second frame Frame2 may be formed by a low injection pressure over-molding (LIPO) process. In detail, in a state where a mold is coupled to the backside surface of the display panel PN or the cover glass CG, a resin for forming the second frame Frame2 may be implanted into an internal space of the mold with low pressure and may then be cured, and thus, the second frame Frame2 may be formed. As described above, the resin cured in the mold may form the second frame Frame2 including a stiff material. This will be described below in detail with reference to FIGS. 5A to 5C.

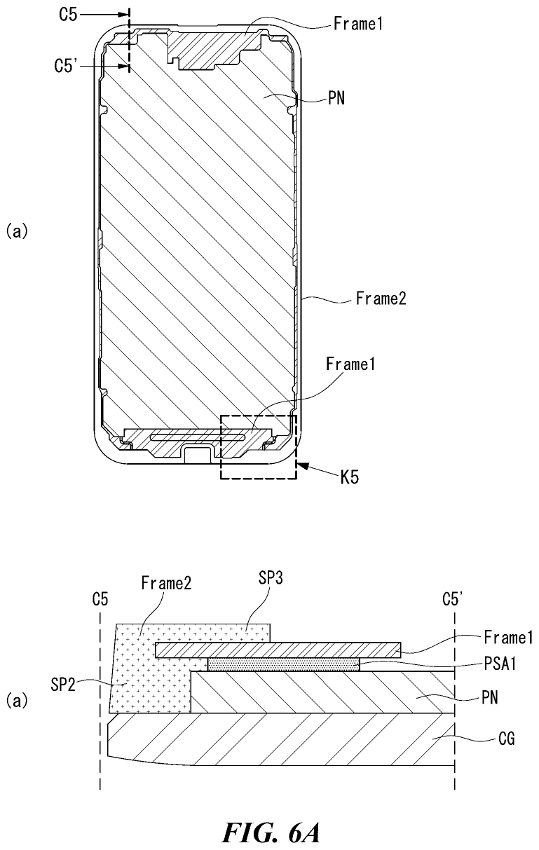

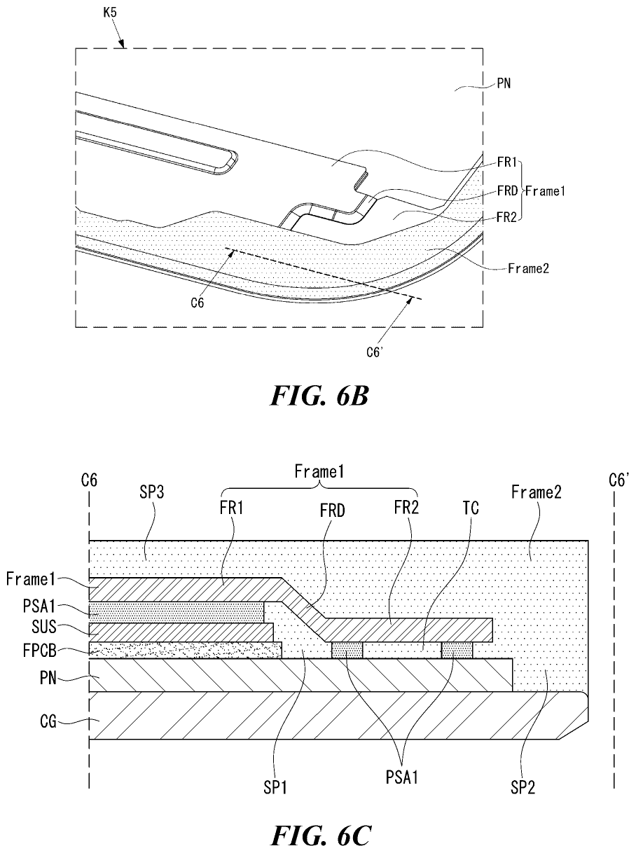

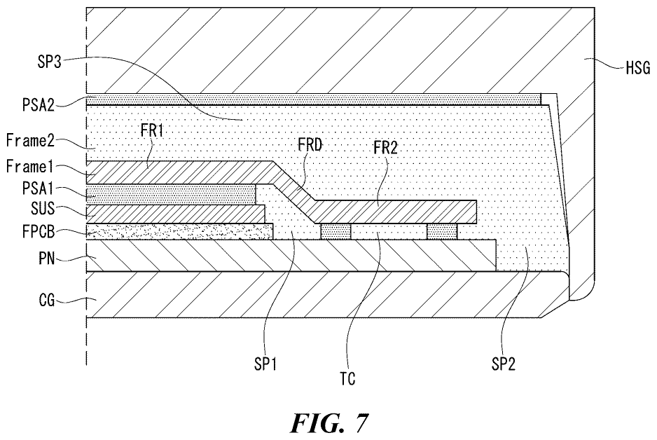

For example, the second frame Frame2 may be disposed in a first space formed between a side surface of the flexible printed circuit board FPCB and the stepped portion of the first frame Frame1, a second space formed between the housing HSG, a backside surface of an edge of the cover glass CG, an outer surface of the display panel PN, and an outer surface of the first frame Frame1, and a third space formed between the housing HSG and the first frame Frame1. An example where the second frame Frame2 is disposed in the first to third spaces will be described below in detail with reference to FIGS. 6A to 7.

The second frame Frame2 may be disposed to plug an empty gap or space between the cover glass CG, the display panel PN, the flexible printed circuit board FPCB, and the first frame Frame1, and thus, may enhance a waterproof function of the display apparatus 100.

Moreover, the second frame Frame2 may be disposed between an outer end of the first frame Frame1 and a side surface of the display panel PN or between the outer end of the first frame Frame1 and an edge of the cover glass CG, and thus, stress applied to the display panel PN due to a tolerance of the first frame Frame1 may be reduced, or the warpage of the cover glass may be prevented.

Moreover, the second frame Frame2 may absorb an external impact applied to the first frame Frame1 to prevent the display panel PN or the cover glass CG from being damaged by the first frame Frame1.

The housing HSG may include a space where the display panel PN, the first frame Frame1, and the second frame Frame2 are disposed therein, the first frame Frame1, the second frame Frame2, and the display panel PN may be accommodated into the housing HSG, and the housing HSG may be coupled to an outer surface of the cover glass CG. The housing HSG may protect the display panel PN from an external impact.

Furthermore, in the display apparatus 100, the first adhesive layer PSA1 may include a trapping cavity forming a space therein, so that a resin forming the second frame Frame2 more completely plugs a fine gap or a space formed between a side surface of an edge of the flexible printed circuit board FPCB and the display panel PN.

Hereinafter, a structure of each of the display panel PN, the first adhesive layer PSA1, the first frame Frame1, and the second frame Frame2 will be described in more detail.

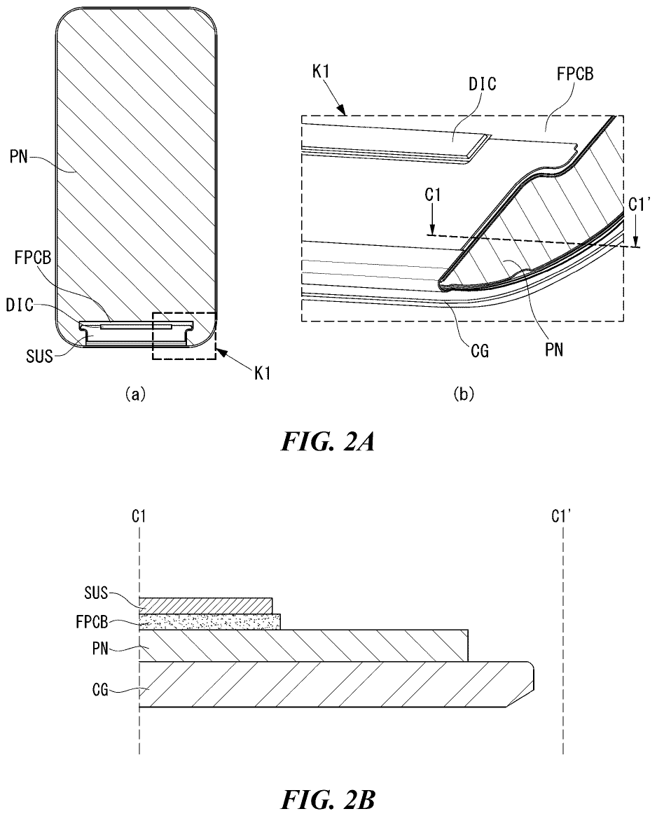

FIGS. 2A and 2B are diagrams for describing an embodiment of a structure where a flexible printed circuit board is disposed on a backside surface of a display panel.

FIG. 2A (a) is a plan view of a backside surface of a display panel PN, FIG. 2A (b) is an enlarged perspective view of a region K1 of FIG. 2A (a), and FIG. 2B is a cross-sectional view taken along line C1-C1′ of FIG. 2A (b).

The display panel PN may be disposed on a cover glass CG, and as illustrated in FIG. 2A (a) and (b), a flexible printed circuit board FPCB may be disposed in a partial region of a backside edge of the display panel PN, and a data driving chip DIC may be disposed in a partial region of the flexible printed circuit board FPCB.

Furthermore, a reinforcing plate SUS which prevents the warpage of the flexible printed circuit board FPCB may be disposed in the other region except a region, where the data driving chip DIC is disposed, of the flexible printed circuit board FPCB. The reinforcing plate SUS may include a stiff metal material such as stainless steel or aluminum.

Therefore, in a cross-sectional surface taken along line C1-C1′ of FIG. 2A (b), as illustrated in FIG. 2B, the cover glass CG, the display panel PN, the flexible printed circuit board FPCB, and the reinforcing plate SUS may be sequentially arranged.

The display panel PN may have an area which is less than that of the cover glass CG, and as illustrated in FIG. 2B, an end of the display panel PN may be disposed on an edge of a backside surface of the cover glass CG disposed more inward than an end of the cover glass CG. An end of each of the flexible printed circuit board FPCB and the reinforcing plate SUS may be disposed on a backside surface of the display panel PN disposed more inward than the end of the display panel PN.

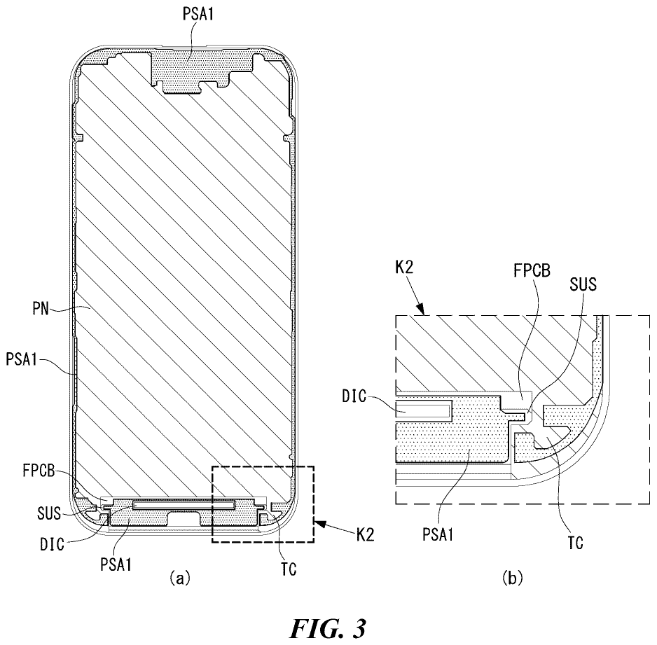

FIG. 3 is a diagram for describing an embodiment of a structure where a first adhesive layer is disposed on a backside surface of a display panel. In detail, FIG. 3(a) is a plan view of a backside surface of a display panel PN where a first adhesive layer PSA1 is disposed, and FIG. 3(b) is an enlarged view of a region K2 of FIG. 3(a).

As illustrated in FIGS. 3(a) and (b), the first adhesive layer PSA1 may be disposed in an edge region, except a center region, of the backside surface of the display panel PN. The first adhesive layer PSA1 may be patterned and disposed in a relatively wide region so as to increase an adhesive force, based on a step height of a lower region of the backside surface of the display panel PN caused by a flexible printed circuit board FPCB and a reinforcing plate SUS.

In a lower region of the display panel PN, the first adhesive layer PSA1 may be disposed on the flexible printed circuit board FPCB, the reinforcing plate SUS, and a data driving chip DIC and may be disposed on the display panel PN along an edge periphery of the flexible printed circuit board FPCB.

As illustrated in FIG. 3(b), in order to more precisely plug a fine gap formed by a step height caused by the flexible printed circuit board FPCB and the reinforcing plate SUS, the first adhesive layer PSA1 disposed on the display panel PN along a periphery of the flexible printed circuit board FPCB may include a trapping cavity TC which is spaced apart from the first adhesive layer PSA1 disposed on the flexible printed circuit board FPCB and forms a space.

In a state where a first frame Frame1 is disposed on the first adhesive layer PSA1, a resin for forming the second frame Frame2 may be implanted into a mold and may then be cured, and thus, a second frame Frame2 may be formed.

When implanting a resin for forming the second frame Frame2, the trapping cavity TC included in the first adhesive layer PSA1 may allow a resin overflowing along a side surface of an edge of the flexible printed circuit board FPCB to be trapped in a space of the trapping cavity TC. That is, the implanted resin may be filled into an internal space of the trapping cavity TC.

A resin first trapped in the trapping cavity TC of the first adhesive layer PSA1 may obstruct an overflowing path of a resin which is implanted subsequently, and thus, a resin may completely plug a fine gap or a space formed between the side surface of the edge of the flexible printed circuit board FPCB and the display panel PN.

Moreover, a resin may be disposed in the trapping cavity TC of the first adhesive layer PSA1, and thus, the second frame Frame2 may be more solidly coupled to the backside surface of the display panel PN.

FIGS. 4A to 4E are diagrams for describing an embodiment of a connection relationship between a display panel, a first adhesive layer, and a first frame according to the present disclosure.

FIG. 4A is a plan view illustrating a state where a first frame Frame1 is disposed on a backside surface of a display panel PN, FIG. 4B illustrates an example of a pattern of the first frame Frame1, FIG. 4B (a) is a plan view illustrating a backside surface of the first frame Frame1, and FIG. 4B (b) is a plan view illustrating a state where a first adhesive layer PSA1 is patterned on a front-side surface of the first frame Frame1.

Here, the backside surface of the first frame Frame1 may be a surface when the first frame Frame1 is seen from a housing HSG, and the front-side surface of the first frame Frame1 may be a surface when the first frame Frame1 is seen from a display panel PN.

As in FIG. 4A, the first frame Frame1 may be disposed along an edge region of the backside surface of the display panel PN to cover the first adhesive layer PSA1. As illustrated in FIG. 4B (a), the first frame Frame1 may have a size similar to an area size of a backside region of the display panel PN, and a center portion of the first frame Frame1 may have an opened structure.

Moreover, as illustrated in FIG. 4B (b), the first adhesive layer PSA1 may be patterned on the front-side surface of the first frame Frame1. When the first frame Frame1 is disposed on the backside surface of the display panel PN through a press thereof in a state where the first adhesive layer PSA1 is patterned on the front-side surface of the first frame Frame1, the first adhesive layer PSA1 may be adhered to the backside surface of the display panel PN together.

FIG. 4C is an enlarged plan view of a region K3 of FIG. 4B (b), FIG. 4D is an enlarged perspective view of a region K4 of FIG. 4A, and FIG. 4E is a cross-sectional view taken along line C2-C2′ of FIG. 4D. A structure of the first frame Frame1 and the first adhesive layer PSA1 illustrated in the cross-sectional view of FIG. 4E may be the same as a cross-sectional surface taken along line C2-C2′ illustrated in FIG. 4C.

As illustrated in FIG. 4C, the first frame Frame1 may include a first portion FR1, a second portion FR2, and a stepped portion FRD. The first portion FR1 may cover the flexible printed circuit board FPCB, a data driving chip DIC, and a reinforcing plate SUS, and the second portion FR2 may cover an edge, including a peripheral region of the flexible printed circuit board FPCB, of the backside surface of the display panel PN. The stepped portion FRD of the first frame Frame1 may connect the first portion FR1 to the second portion FR2 and may be provided to be inclined.

In detail, the first adhesive layer PSA1 may be disposed between the first portion FR1 of the first frame Frame1 and the flexible printed circuit board FPCB and between the second portion FR2 and the display panel PN.

The first adhesive layer PSA1 may attach the first portion FR1 of the first frame Frame1 to the flexible printed circuit board FPCB, the data driving chip DIC, and the reinforcing plate SUS and may attach the second portion FR2 of the first frame Frame1 to the backside surface of the display panel PN.

As the first frame Frame1 is disposed on the backside surface of the display panel PN, a step height may be between a region where the flexible printed circuit board FPCB is disposed and a region where the flexible printed circuit board FPCB is not disposed, on the backside surface of the display panel PN.

In detail, as in FIGS. 4D and 4E, a step height may be between the first portion FR1 and the second portion FR2 of the first frame Frame2. An interval up to the first portion FR1 of the first frame Frame1 from the backside surface of the display panel PN may be greater than an interval up to the second portion FR2 of the first frame Frame1 from the backside surface of the display panel PN.

The stepped portion FRD of the first frame Frame1 may extend from the first portion FR1 to the second portion FR2 and may connect the first portion FR1 to the second portion FR2, and thus, may be provided in an inclined shape.

As in FIGS. 4D and 4E, a first space SP1 which is a fine gap may be formed between a side surface of the flexible printed circuit board FPCB and the stepped portion FRD of the first frame Frame1.

As in FIGS. 4C to 4E, a trapping cavity TC may be disposed outside the flexible printed circuit board FPCB and may have a structure which is surrounded by the first adhesive layer PSA1 and may be disposed between the second portion FR2 of the first frame Frame1 and the display panel PN. Accordingly, as in FIG. 4E, a height of the trapping cavity TC may be the same as a thickness of the first adhesive layer PSA1.

A space formed by the trapping cavity TC may be connected to the first space SP1. For example, as in FIGS. 4C to 4E, an internal space of the trapping cavity TC may be connected to the first space SP1. Accordingly, when a resin overflows through the first space SP1, the resin may flow into the trapping cavity TC.

Therefore, when performing a process where a resin forming the second frame Frame2 is implanted into a mold, a resin which is first trapped in the trapping cavity TC may press a resin which is implanted subsequently, and thus, a subsequently implanted resin may be more tightly adhered to a side surface of the flexible printed circuit board FPCB, a side surface of the reinforcing plate SUS, or a side surface of the first adhesive layer PSA1. Accordingly, a resin may more completely plug the first space SP1. That is, the trapping cavity TC may be disposed so that the second frame Frame2 more completely plugs an inner portion of the first space SP1.

Moreover, as the second frame Frame2 is disposed in the trapping cavity TC, the second frame Frame2 may be more solidly coupled to the backside surface of the display panel PN in structure.

As in FIGS. 4C to 4E, in a case where the first space SP1 includes a bending portion FRDB which extends along an outer side of the flexible printed circuit board FPCB and is bent, the trapping cavity TC may be disposed to contact the bending portion FRDB of the first space SP1. Accordingly, in a case where a resin overflows along the first space SP1, the bending portion FRDB may induce the resin to be first filled into the trapping cavity TC naturally.

Here, a greatest width W1 forming an area of the trapping cavity TC may be greater than a width W2 of the stepped portion FRD. Accordingly, a trapped resin may apply sufficient pressure to a resin which is implanted subsequently.

An outer end of the first frame Frame1 may be spaced apart from the display panel PN or the cover glass CG. That is, an outer end of the second portion FR2 of the first frame Frame1 may not be bent in a direction toward the cover glass CG and may be parallel to the backside surface of the cover glass CG or the display panel PN.

When the outer end of the first frame Frame1 is bent in a direction toward the cover glass CG, a bent end of the first frame Frame1 may press the display panel PN or the cover glass CG, based on a tolerance of a bent length, and due to this, a phenomenon where the display panel PN or the cover glass CG is warped may occur.

However, the outer end of the first frame Frame1 may extend in parallel with a surface direction of the display panel PN or the cover glass CG and may allow the display panel PN to be spaced apart from the cover glass CG, and thus, a phenomenon where the display panel PN or the cover glass CG is warped may be prevented based on a tolerance of the first frame Frame1.

The second frame Frame2 may be disposed in at least one of a region between the outer end of the first frame Frame1 and the side surface of the display panel PN and a region between the outer end of the first frame Frame1 and an edge of the cover glass CG.

Accordingly, the display apparatus 100 according to the present disclosure may prevent a phenomenon where the display panel PN or the cover glass CG is warped, and moreover, when an external impact is applied, the second frame Frame2 may absorb the impact to alleviate the damage of an edge portion of the display panel PN.

A structure may be described where an outer surface of the cover glass CG is coupled to a mold for forming the second frame Frame2 in the cover glass CG where the display panel PN, the flexible printed circuit board FPCB, and the first frame Frame1 are disposed.

FIGS. 5A to 5C are diagrams for describing an embodiment where a mold is coupled to a cover glass to form a second frame according to an embodiment of the present disclosure. In detail, FIG. 5A is a plan view where a mold for forming a second frame is coupled to a cover glass where a display panel, a flexible printed circuit board, and a first frame are disposed, FIG. 5B illustrates an example of a cross-sectional surface taken along line C3-C3′ of FIG. 5A, and FIG. 5C illustrates an example of a cross-sectional surface taken along line C4-C4′ of FIG. 5A.

As illustrated in FIG. 5A, a mold MD for forming a second frame Frame2 may be coupled to a cover glass CG where a display panel PN, a flexible printed circuit board FPCB, and a first frame Frame1 are disposed. In FIG. 5A, for convenience of understanding, an upper surface of the mold MD is omitted so that a space exposed at an inner portion of the mold MD is displayed.

The mold MD coupled to the cover glass CG may include a light-transmissive material and may be transparent.

As illustrated in FIGS. 5A to 5C, an inner surface forming an internal space of the mold MD may be coupled to an outer surface of the cover glass CG.

In FIG. 5A, for convenience of understanding, it is illustrated that first and second portions FR1 and FR2 of the first frame Frame1 are exposed at the internal space of the mold MD, but as illustrated in FIGS. 5B and 5C, for example, a backside surface of an edge of the cover glass CG, an outer surface of the display panel PN, a side surface of the flexible printed circuit board FPCB, and outer surfaces and upper surfaces of the first and second portions FR1 and FR2 of the first frame Frame1 may be exposed at the internal space of the mold MD.

A resin implanted into the internal space of the mold MD may fill a first space SP1 formed by the side surface of the flexible printed circuit board FPCB and a stepped portion FRD of the first frame Frame1, a second space SP2 formed by the backside surface of the edge of the cover glass CG, the outer surface of the display panel PN, and the outer surface of the first frame Frame1, and a third space SP3 at which the upper surface of the first frame Frame1 is exposed.

In detail, as illustrated in FIGS. 5A to 5C, in a state where the mold MD is coupled to the outer surface of the cover glass CG, a resin forming the second frame Frame2 may be implanted through a mold hole HMD included in the mold MD. The resin implanted through the mold hole HMD may fill the first space SP1, the second space SP2, and the third space SP3.

The resin implanted into the first space SP1, as described above, may fill a trapping cavity TC connecting with the first space SP1 and may be tightly adhered to a side surface of a first adhesive layer PSA1, a side surface of a reinforcing plate SUS, and the side surface of the flexible printed circuit board FPCB, and moreover, may fill a fine gap of the first space SP1 and may fill the second space SP2 and the third space SP3.

As described above, in a state where the first space SP1, the second space SP2, and the third space SP3 are filled by a resin, the resin may be solidly cured by irradiating ultraviolet (UV) from the outside of the transparent mold MD. Accordingly, a second frame Frame2 where a resin is solidly cured may be disposed in the first space SP1, the second space SP2, and the third space SP3.

FIGS. 6A to 6C are diagrams for describing an embodiment of a structure where a second frame according to an embodiment of the present disclosure is disposed at an edge of each of a display panel and a cover glass. In detail, FIG. 6A (a) is a plan view where a second frame is disposed at an edge of each of a cover glass and a display panel, FIG. 6A (b) illustrates a cross-sectional surface taken along line C5-C5′ of FIG. 6A (a), FIG. 6B is an enlarged perspective view of a region K5 of FIG. 6A, and FIG. 6C illustrates a cross-sectional surface taken along line C6-C6′ of FIG. 6B.

As illustrated in FIG. 6A (a), a second frame Frame2 may be disposed at an edge of each of a cover glass CG and a display panel PN. As in FIG. 6A (b), the second frame Frame2 may be disposed to cover an edge of a backside surface of the cover glass CG, an outer surface of the display panel PN, an outer surface of a first adhesive layer PSA1, and an outer surface and an upper surface of a first frame Frame1.

As in FIGS. 6B and 6C, the second frame Frame2 may be disposed in a first space SP1 and an internal space of the trapping cavity TC, and the second frame Frame2 may be adhered to and disposed on a side surface of each of the flexible printed circuit board FPCB, a reinforcing plate SUS, and the first adhesive layer PSA1 by the trapping cavity TC.

Furthermore, the second frame Frame2 may be disposed in a second space SP2 and a third space SP3.

FIG. 7 is a diagram for describing an embodiment of a structure where a housing is coupled to a cover glass in a state where a second frame according to an embodiment of the present disclosure is disposed at an edge of each of a display panel and the cover glass.

As illustrated in FIG. 7, a housing HSG may include a sidewall and a bottom surface, which form a space where a display panel PN, a first frame Frame1, and a second frame Frame2 are disposed.

The bottom surface of the housing HSG may have an area similar to that of a cover glass CG and may have a planar shape similar to a planar shape of the cover glass CG. The bottom surface of the housing HSG may cover backside surfaces of the display panel PN and the first and second frames Frame1 and Frame2.

A second adhesive layer PSA2 may be disposed between the second frame Frame2 and the housing HSG, which are disposed in the second space SP2. The bottom surface of the housing HSG may be attached to the second frame Frame2 through the second adhesive player PSA2, and an inner surface of a sidewall of the housing HSG may be coupled to an outer surface of the cover glass CG.

The second adhesive layer PSA2 may include a pressure sensitive adhesive (PSA) including various materials such as silicon, a thermoplastic material, and an organic material.

As in FIG. 7, the second frame Frame2 may be disposed in an internal space of a trapping cavity TC as well as a first space SP1 and may be disposed in the second space SP2 formed between the housing HSG, a backside surface of an edge of the cover glass CG, an outer surface of the display panel PN, and an outer surface of the first frame Frame1 and a third space SP3 formed between the housing HSG and the first frame Frame1.

As described above, embodiments of the present disclosure may include the trapping cavity TC connected with the first space SP1 formed by a stepped portion FRD of the first frame Frame1, in the first adhesive layer PSA1, and thus, the second frame Frame2 may more precisely plug a fine gap between the first frame Frame1 and the display panel PN to enhance waterproof performance.

Moreover, in embodiments of the present disclosure, an outer end of the first frame Frame1 may not contact the cover glass CG, and the second frame Frame2 may be disposed between the first frame Frame1 and the cover glass CG, and thus, stress applied to the display panel PN due to a tolerance of the first frame Frame1 may be blocked, and the warpage of the cover glass CG may be prevented.

Embodiments of the present disclosure may include a trapping cavity connected with a first space formed by a stepped portion of a first frame, in a first adhesive layer, and thus, a second frame may more precisely plug a fine gap between the first frame and a display panel to enhance waterproof performance.

In more detail, when manufacturing a display apparatus, a resin for forming the second frame may be trapped in the trapping cavity through a first space in the middle of a second frame formation process, a trapped resin may obstruct a path of resin implanted into the first space subsequently, and a subsequently implanted resin may plug a fine gap between the first frame and the display panel and may then overflow through the first space. Accordingly, the trapping cavity may further enhance a waterproof function of a display apparatus.

Moreover, in embodiments of the present disclosure, an outer end of the first frame may not contact a cover glass, and the second frame may be disposed between the first frame and the cover glass, and thus, stress applied to the display panel due to a tolerance of a first frame may be blocked, and the warpage of the cover glass may be prevented.

The effects according to the present disclosure are not limited to the above examples, and other various effects may be included in the specification.

While the present disclosure has been particularly shown and described with reference to exemplary embodiments thereof, it will be understood by those of ordinary skill in the art that various changes in form and details may be made therein without departing from the spirit and scope of the present disclosure including those of the following claims.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a cover glass;
a display panel disposed on the cover glass and configured to display an image on a front-side surface;
a flexible printed circuit board disposed on a partial region of a backside surface of the display panel;
a first frame including a first portion covering the flexible printed circuit board, a second portion covering an edge of the backside surface of the display panel, and a stepped portion connecting the first portion to the second portion, the stepped portion being inclined;
a first adhesive layer disposed between the first portion of the first frame and the flexible printed circuit board and between the second portion of the first frame and the display panel;
a housing accommodating the first frame and the display panel therein and coupled to an outer surface of the cover glass; and
a second frame disposed along the first frame and disposed in a first space between a side surface of the flexible printed circuit board and the stepped portion of the first frame,
wherein the first adhesive layer comprises a trapping cavity forming a space between the display panel and the first frame, and the space is connected to the first space.

2. The display apparatus of claim 1, wherein the trapping cavity is surrounded by the first adhesive layer.

3. The display apparatus of claim 1, wherein the first space comprises a bending portion extending along an outer side of the flexible printed circuit board and bent, and
the trapping cavity contacts the bending portion of the first space.

4. The display apparatus of claim 1, wherein a greatest width of the trapping cavity is greater than a width of the stepped portion.

5. The display apparatus of claim 1, wherein a height of the trapping cavity is same as a thickness of the first adhesive layer.

6. The display apparatus of claim 1, wherein the second frame is disposed in the trapping cavity.

7. The display apparatus of claim 1, wherein the second frame is disposed in a second space between the housing, a backside surface of an edge of the cover glass, an outer surface of the display panel, and an outer surface of the first frame.

8. The display apparatus of claim 1, wherein an outer end of the first frame is spaced apart from the display panel or the cover glass, and
the second frame is disposed in at least one of a first region between an outer end of the first frame and a side surface of the display panel or a second region between the outer end of the first frame and an edge of the cover glass.

9. The display apparatus of claim 1, wherein the second frame is disposed in a third space formed between the housing and the first frame.

10. The display apparatus of claim 1, wherein the first frame and the second frame comprise different materials.

11. The display apparatus of claim 1, wherein the first frame comprises a metal material, and
the second frame comprises a polymer including resin or plastic.

12. The display apparatus of claim 1, wherein a first interval between the first portion of the first frame and the backside surface of the display panel is greater than a second interval between the second portion of the first frame and the backside surface of the display panel.

13. The display apparatus of claim 7, further comprising a second adhesive layer disposed between the housing and the second frame disposed in the second space.

14. The display apparatus of claim 1, wherein each of the first and second adhesive layers comprises a pressure sensitive adhesive (PSA).

15. The display apparatus of claim 1, further comprising a data driving chip disposed on the flexible printed circuit board configured to supply the display panel with a data voltage for displaying an image,
wherein the first portion of the first frame is disposed on the data driving chip.

16. The display apparatus of claim 1, further comprising a reinforcing plate disposed on the flexible printed circuit board and including a metal material,
wherein the first portion of the first frame is disposed on the reinforcing plate.
